(19) United States
(12) Patent Application Publication
(10) Pub. No.: US 2026/0190845 A1
(43) Pub. Date: Jul. 2, 2026

(54) Display Apparatus Having an Encapsulation Dam

(71) Applicant: LG Display Co., Ltd., Seoul (KR)

(72) Inventors: Myeong Su Kim, Paju-si (KR); Jong Moo Ha, Paju-si (KR); Se Yong Lee, Paju-si (KR)

(21) Appl. No.: 19/413,531

(22) Filed: Dec. 9, 2025

(30) Foreign Application Priority Data
Dec. 31, 2024 (KR) 10-2024-0202818

(51) Int. Cl. H10K 59/88; H10K 59/131; H10K 59/80

(52) U.S. Cl. CPC H10K 59/88; H10K 59/131; H10K 59/873

(57) ABSTRACT

A display apparatus including an encapsulation dam is provided. The display apparatus includes a device substrate. A light-emitting device is disposed on a display area of the device substrate. The device substrate includes a bezel area disposed outside the display area. The encapsulation dam is disposed on the bezel area of the device substrate. A power voltage supply line and a dummy line are disposed between the device substrate and the encapsulation dam. A first side surface of the encapsulation dam toward the display area overlaps the power voltage supply line and the dummy line. The amount of light reflected by the dummy line disposed between the power voltage supply line and the first side surface of the encapsulation dam is smaller than the amount of light reflected by the power voltage supply line. Thus, in the display apparatus, the encapsulation dam can be stably formed by an exposure process.

### CROSS-REFERENCE TO RELATED APPLICATION

This application claims the priority of Republic of Korea Patent Application No. 10-2024-0202818, filed on Dec. 31, 2024, which is incorporated by reference in its entirety.

### BACKGROUND

### Field

The present disclosure relates to a display apparatus in which a display area is surrounded by an encapsulation dam.

### Description of the Related Art

Generally, a display apparatus provides an image to a user. For example, the display apparatus can include a light-emitting device. The light-emitting device can emit light displaying a specific color. For example, the light-emitting device can include a light-emitting unit between a first electrode and a second electrode.

An encapsulation structure can be disposed on the light-emitting device. The encapsulation structure can include an organic encapsulating layer disposed between inorganic encapsulating layers. A display area in which the light-emitting device is disposed can be surrounded by an encapsulation dam. A region in which the organic encapsulating layer is formed can be defined by the encapsulation dam.

### SUMMARY

Accordingly, the present disclosure is directed to a display apparatus that substantially obviates one or more problems due to limitations and disadvantages of the related art.

An object of the present disclosure is to provide a display apparatus capable of stably forming the encapsulation dam.

Another object of the present disclosure is to provide a display apparatus capable of reducing the reflection of light due to a power voltage supply line disposed between a device substrate and a first side surface of the encapsulation dam.

Additional advantages, objects, and features of the disclosure will be set forth in part in the description which follows and in part will become apparent to those having ordinary skill in the art upon examination of the following or may be learned from practice of the disclosure. The objectives and other advantages of the disclosure may be realized and attained by the structure particularly pointed out in the written description and claims hereof as well as the appended drawings.

To achieve these objects and other advantages and in accordance with the purpose of the present disclosure, as embodied and broadly described herein, there is provided a display apparatus comprising a device substrate. The device substrate includes a display area and a bezel area. The bezel area is disposed outside the display area. A power voltage supply line is disposed on the bezel area of the device substrate. An encapsulation dam is disposed on the power voltage supply line of the bezel area. The encapsulation dam includes a first side surface toward the display area. A dummy line is disposed between the power voltage supply line and the first side surface of the encapsulation dam. The first side surface of the encapsulation dam overlaps the power voltage supply line and the dummy line. A reflectivity of the dummy line is less than a reflectivity of the power voltage supply line.

The dummy line can have a smaller size than the power voltage supply line.

The dummy line can include a conductive material.

The dummy line can include a metal.

The power voltage supply line can be electrically connected to the dummy line.

The power voltage supply line can include a first supply line and a second supply line. The second supply line can be disposed on the first supply line. The second supply line can include a different material from the first supply line. The second supply line can include a region being in contact with the dummy line.

The dummy line can include a first line and a second line. The first line can overlap the first side surface of the encapsulation dam. The second line can be spaced apart from the first line.

A middle stopper can be disposed between the display area and the encapsulation dam. The middle stopper can have a smaller size than the encapsulation dam. A side surface of the middle stopper can overlap the power voltage supply line and the second line.

The encapsulation dam can include a first dam pattern and a second dam pattern. The second dam pattern can be disposed on the first dam pattern. The dummy line can extend between the first dam pattern and the second dam pattern.

The dummy line can include an end portion covered by the second dam pattern.

In another embodiment, there is provided a display apparatus comprising a display area. The display area is surrounded by an encapsulation dam. A power voltage supply line and a dummy line are disposed outside the display area. The power voltage supply line extends an edge of the display area. The dummy line overlaps the power voltage supply line. The dummy line extends parallel to the power voltage supply line. The encapsulation dam includes a first side surface and a second side surface. The first side surface of the encapsulation dam is toward the display area. The second side surface is opposite to the first side surface. The first side surface of the encapsulation dam includes a region overlapping with the power voltage supply line. The dummy line is disposed between the power voltage supply line and the first side surface of the encapsulation dam. The loss of light due to the dummy line is greater than the loss of light due to the power voltage supply line.

The dummy line can include an insulating material.

The dummy line can include dummy patterns disposed side by side along the power voltage supply line.

A space between adjacent dummy patterns can have a smaller size than each dummy pattern.

A light-emitting device can be disposed in the display area. The light-emitting device can include a first electrode, a light-emitting unit and a second electrode, which are sequentially stacked. One of layers constituting the power voltage supply line can include a same material as the first electrode of the light-emitting device. The second electrode of the light-emitting device can be electrically connected to the power voltage supply line.

### BRIEF DESCRIPTION OF THE DRAWINGS

The accompanying drawings, which are included to provide a further understanding of the present disclosure and are incorporated in and constitute a part of this application, illustrate embodiment(s) of the present disclosure and together with the description serve to explain the principle of the present disclosure. In the drawings:

FIG. 1 is a view schematically showing a display apparatus according to an embodiment of the present disclosure.

FIG. 2 is a view showing a display area of a display panel in the display apparatus according to the embodiment of the present disclosure.

FIG. 3 is a view showing a circuit of a pixel area in the display apparatus according to the embodiment of the present disclosure.

FIG. 4 is a view showing a cross-section of the pixel area in the display apparatus according to the embodiment of the present disclosure.

FIG. 5 is an enlarged view of K1 region in FIG. 1.

FIG. 6 is a view taken along I-I′ of FIG. 5.

FIGS. 7 to 13 are views showing the display apparatus according to another embodiment of the present disclosure.

### DETAILED DESCRIPTION

Hereinafter, details related to the above objects, technical configurations, and operational effects of the embodiments of the present disclosure will be clearly understood by the following detailed description with reference to the drawings, which illustrate some embodiments of the present disclosure. Here, the embodiments of the present disclosure are provided in order to allow the technical sprit of the present disclosure to be satisfactorily transferred to those skilled in the art, and thus the present disclosure may be embodied in other forms and is not limited to the embodiments described below.

In addition, the same or extremely similar elements may be designated by the same reference numerals throughout the specification and in the drawings, the lengths and thickness of layers and regions may be exaggerated for convenience. It will be understood that, when a first element is referred to as being “on” a second element, although the first element may be disposed on the second element so as to come into contact with the second element, a third element may be interposed between the first element and the second element.

Here, terms such as, for example, “first” and “second” may be used to distinguish any one element with another element. However, the first element and the second element may be arbitrary named according to the convenience of those skilled in the art without departing the technical sprit of the present disclosure.

The terms used in the specification of the present disclosure are merely used in order to describe particular embodiments, and are not intended to limit the scope of the present disclosure. For example, an element described in the singular form is intended to include a plurality of elements unless the context clearly indicates otherwise. In addition, in the specification of the present disclosure, it will be further understood that the terms “comprises” and “includes” specify the presence of stated features, integers, steps, operations, elements, components, and/or combinations thereof, but do not preclude the presence or addition of one or more other features, integers, steps, operations, elements, components, and/or combinations.

And, unless ‘directly’ is used, the terms “connected” and “coupled” may include that two components are “connected” or “coupled” through one or more other components located between the two components.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and should not be interpreted in an idealized or overly formal sense unless expressly so defined herein.

### Embodiment

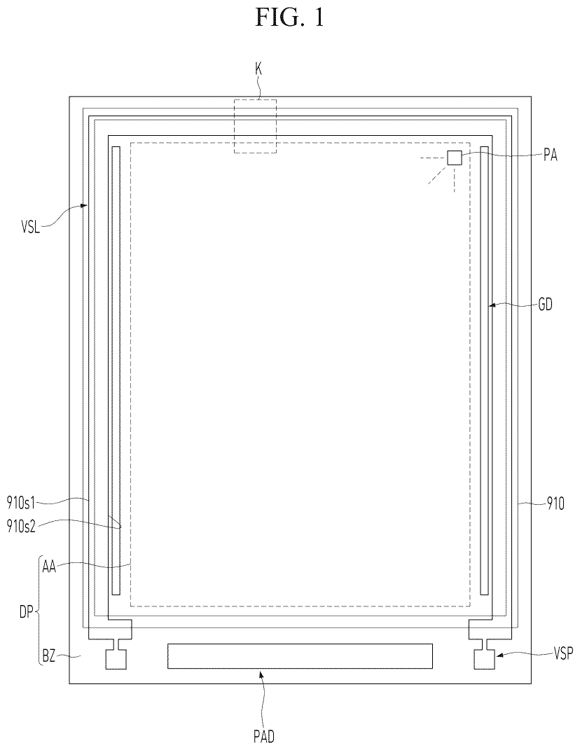

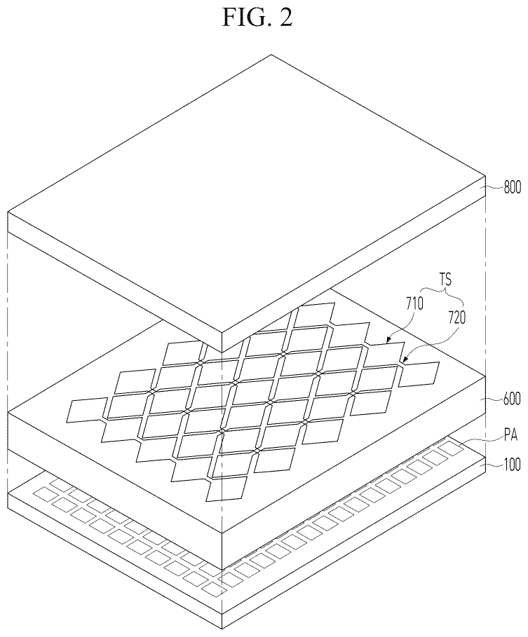

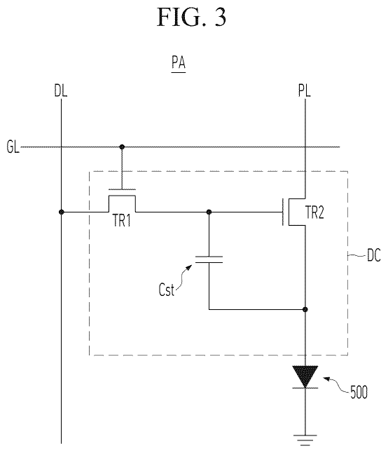

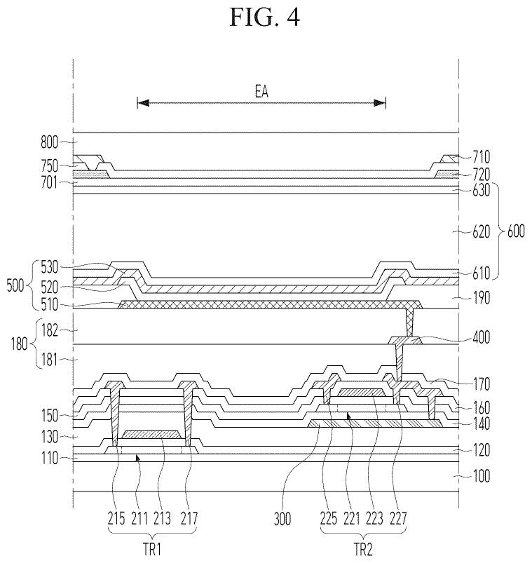

FIG. 1 is a view schematically showing a display apparatus according to an embodiment of the present disclosure. FIG. 2 is a view showing a display area of a display panel in the display apparatus according to the embodiment of the present disclosure. FIG. 3 is a view showing a circuit of a pixel area in the display apparatus according to the embodiment of the present disclosure. FIG. 4 is a view showing a cross-section of the pixel area in the display apparatus according to the embodiment of the present disclosure.

Referring to FIGS. 1 to 4, the display apparatus according to the embodiment of the present disclosure can include a display panel DP. The display panel DP can generate an image provided to a user. For example, the display panel DP can include pixel areas PA. Various signals can be applied in each pixel area PA through signal wirings GL, DL and PL. For example, each of the pixel areas PA can include a driving circuit DC electrically connected to the signal wirings GL, DL and PL, and a light-emitting device 500 electrically connected to the driving circuit DC.

The operation of the light-emitting device 500 can be controlled by the driving circuit DC. The signal wirings GL, DL and PL can include a gate line GL applying a gate signal, a data line DL applying a data signal, and a first power voltage supply line PL supplying a first power voltage. For example, the driving circuit DC can supply a driving current corresponding to the data signal to the light-emitting device 500 according to the gate signal using the first power voltage. The driving current supplied to the light-emitting device 500 by the driving circuit DC can be maintained for one frame. For example, the driving circuit DC can include a first thin film transistor TR1, a second thin film transistor TR2 and a storage capacitor Cst.

The first thin film transistor TR1 can transmit the data signal to the second thin film transistor TR2 according to the gate signal. For example, the first thin film transistor TR1 can function as a switching thin film transistor. The first thin film transistor TR1 can include a first semiconductor pattern 211, a first gate electrode 213, a first drain electrode 215 and a first source electrode 217.

The first semiconductor pattern 211 can include a first drain region electrically connected to the first drain electrode 215, a first source region electrically connected to the first source electrode 217, and a first channel region disposed between the first drain region and the first source region. The first drain electrode 215 can be electrically connected to the data line DL. The first gate electrode 213 can be electrically connected to the gate line GL. The first gate electrode 213 can overlap the first channel region of the first semiconductor pattern 211. The first semiconductor pattern 211 can be insulated from the first gate electrode 213. For example, the first source region of the first semiconductor pattern 211 can be electrically connected to the first drain region of the first semiconductor pattern 211 according to a voltage of a signal applied to the first gate electrode 213.

The second thin film transistor TR2 can generate the driving current corresponding to the data signal using the first power voltage. For example, the second thin film transistor TR2 can function as a driving thin film transistor. The second thin film transistor TR2 can include a second semiconductor pattern 221, a second gate electrode 223, a second drain electrode 225 and a second source electrode 227.

The second semiconductor pattern 221 can include a second drain region electrically connected to the second drain electrode 225, a second source region electrically connected to the second source electrode 227, and a second channel region disposed between the second drain region and the second source region. The second gate electrode 223 can be electrically connected to the first source electrode 217. The second gate electrode 223 can overlap the second channel region of the second semiconductor pattern 221. The second semiconductor pattern 221 can be insulated from the second gate electrode 223. For example, the second channel region of the second semiconductor pattern 221 can have an electrical conductivity corresponding to a voltage of a signal applied to the second gate electrode 223. The second drain electrode 225 can be electrically connected to the first power voltage supply line PL.

A voltage of the signal applied to the second gate electrode 223 can be maintained by the storage capacitor Cst. The storage capacitor Cst can have a stacked structure of capacitor electrodes. For example, the storage capacitor Cst can have a structure in which a first capacitor electrode electrically connected to the second gate electrode 233, and a second capacitor electrode electrically connected to the second source electrode 227 are stacked.

The driving circuit DC of each pixel area PA can be supported by a device substrate 100. The device substrate 100 can include an insulating material. For example, the device substrate 100 can include glass or plastic. At least one insulating layers 110, 120, 130, 140, 150, 160, 170, 180 and 190 for preventing unintended electrical connection can be disposed on the device substrate 100. For example, a lower buffer layer 110, a lower gate insulating layer 120, a separation insulating layer 130, an upper buffer layer 140, an upper gate insulating layer 150, an interlayer insulating layer 160, a device passivation layer 170, a device planarization layer 180 and a bank insulating layer 190 can be disposed on the device substrate 100.

The lower buffer layer 110 can be disposed on the device substrate 100. The lower buffer layer 110 can prevent pollution due to the device substrate 100 in a process of forming the driving circuit DC of each pixel area PA. For example, an upper surface of the device substrate 100 toward the driving circuit DC of each pixel area PA can be covered by the lower buffer layer 110. The first thin film transistor TR1, the second thin film transistor TR2 and the storage capacitor Cst of each pixel area PA can be disposed on the lower buffer layer 110.

The lower gate insulating layer 120 can be disposed on the lower buffer layer 110. The first gate electrode 213 of each pixel area PA can be insulated from the first semiconductor pattern 211 of the corresponding pixel area PA by the lower gate insulating layer 120. For example, the first semiconductor pattern 211 of each pixel area PA can be disposed between the lower buffer layer 110 and the lower gate insulating layer 120.

The separation insulating layer 130 can be disposed on the lower gate insulating layer 120. For example, the first gate electrode 213 of each pixel area PA can be disposed between the lower gate insulating layer 120 and the separation insulating layer 130. A relatively small amount of hydrogen can be contained within the separation insulating layer 130. For example, the separation insulating layer 130 can have a larger thickness than the lower gate insulating layer 120.

The upper buffer layer 140 can be disposed on the separation insulating layer 130. The second semiconductor pattern 221 of each pixel area PA can be disposed on the upper buffer layer 140. A light-blocking pattern 300 overlapping with the second semiconductor pattern 221 of each pixel area PA can be disposed between the separation insulating layer 130 and the upper buffer layer 140 of the corresponding pixel area PA. The light-blocking pattern 300 of each pixel area PA can include a material capable of blocking light. For example, the light-blocking pattern 300 of each pixel area PA can include a metal. Thus, in the display apparatus according to the embodiment of the present disclosure, external light travelling toward the second semiconductor pattern 221 of each pixel area PA through the device substrate 100 can be blocked by the light-blocking pattern 300 of the corresponding pixel area PA. Therefore, in the display apparatus according to the embodiment of the present disclosure, the change in the characteristics of the second thin film transistor TR2 in each pixel area PA due to the external light can be prevented.

The upper gate insulating layer 150 can be disposed on the upper buffer layer 140. The second gate electrode 223 of each pixel area PA can be insulated from the second semiconductor pattern 221 of the corresponding pixel area PA by the upper gate insulating layer 150. For example, the second semiconductor pattern 221 of each pixel area PA can be disposed between the upper buffer layer 140 and the upper gate insulating layer 150.

The interlayer insulating layer 160 can be disposed on the upper gate insulating layer 150. The second drain electrode 225 and the second source electrode 227 of each pixel area PA can be insulated from the second gate electrode 223 of the corresponding pixel area PA by the interlayer insulating layer 160. For example, the second gate electrode 223 of each pixel area PA can be disposed between the upper gate insulating layer 150 and the interlayer insulating layer 160. The first drain electrode 215 and the first source electrode 217 of each pixel area PA can be disposed on a same layer as the second drain electrode 225 and the second source electrode 227 of the corresponding pixel area PA. For example, the first drain electrode 215, the first source electrode 217, the second drain electrode 225 and the second source electrode 227 of each pixel area PA can be disposed on the interlayer insulating layer 160.

The device passivation layer 170 can be disposed on the interlayer insulating layer 160. The device passivation layer 170 can prevent the damage of the driving circuit DC in each pixel area PA due to external impact and moisture. For example, the first drain electrode 215, the first source electrode 217, the second drain electrode 225 and the second source electrode 227 of each pixel area PA can be disposed between the interlayer insulating layer 160 and the device passivation layer 170.

The device planarization layer 180 can be disposed on the device passivation layer 170. The device planarization layer 180 can remove a thickness difference due to the driving circuit DC of each pixel area PA. For example, an upper surface of the device planarization layer 180 opposite to the device substrate 100 can be flat. The device planarization layer 180 can include a material having a relatively higher fluidity than the lower buffer layer 110, the lower gate insulating layer 120, the separation insulating layer 130, the upper buffer layer 140, the upper gate insulating layer 150, the interlayer insulating layer 160 and the device passivation layer 170. For example, the lower buffer layer 110, the lower gate insulating layer 120, the separation insulating layer 130, the upper buffer layer 140, the upper gate insulating layer 150, the interlayer insulating layer 160 and the device passivation layer 170 can be an inorganic insulating layer made of an inorganic insulating material, and the device planarization layer 180 can be an organic insulating layer made of an organic insulating material.

The device planarization layer 180 can have a multi-layer structure. For example, the device planarization layer 180 can include a lower planarization layer 181 and an upper planarization layer 182 disposed on the lower planarization layer 181. Thus, in the display apparatus according to the embodiment of the present disclosure, the thickness difference due to the driving circuit DC of each pixel area PAC can be effectively removed. The upper planarization layer 182 can include a same material as the lower planarization layer 181. For example, a boundary between the lower planarization layer 181 and the upper planarization layer 182 can't be recognized.

The light-emitting device 500 of each pixel area PA may be disposed on the upper surface of the device planarization layer 180. The light-emitting device 500 of each pixel area PA can emit light displaying a specific color. For example, the light-emitting device 500 of each pixel area PA can include a first electrode 510, a light-emitting unit 520 and a second electrode 530, which are sequentially stacked on the upper surface of the device planarization layer 180.

The light-emitting unit 520 can generate light having luminance corresponding to a voltage difference between the first electrode 510 and the second electrode 530. For example, the light-emitting unit 520 can include at least one emission material layer (EML). The first electrode 510 and the second electrode 530 can include a conductive material. The second electrode 530 can include a different material from the first electrode 510. For example, the first electrode 510 can be a reflective electrode including a metal, such as aluminum (Al) and silver (Ag), and the second electrode 530 can be a transparent electrode made of a transparent conductive material, such as ITO and IZO. Thus, in the display apparatus according to the embodiment of the present disclosure, the light generated by the light-emitting unit 520 can be emitted outside through the second electrode 530.

The bank insulating layer 190 can be disposed on the device planarization layer 180. The bank insulating layer 190 can include an insulating material. For example, the bank insulating layer can be an organic insulating layer made of an organic insulating material. An edge of the first electrode 510 in each pixel area PA can be covered by the bank insulating layer 190. For example, the bank insulating layer 190 can define an emission area EA in which light is generated in each pixel area PA. The light-emitting unit 520 of each pixel area PA can be in direct contact with the first electrode 510 and the second electrode 530 of the corresponding pixel area PA in the emission area EA of the corresponding pixel area PA. The first electrode 510 of each pixel area PA can be insulated from the first electrode 510 of adjacent pixel area PA by the bank insulating layer 190.

Connecting electrodes 400 can be disposed between the lower planarization layer 181 and the upper planarization layer 182. The connecting electrodes 400 can include a conductive material. The connecting electrodes 400 can include a material having a relative small resistance. For example, the connecting electrodes 400 can include a metal. The first electrode 510 of each pixel area PA can be electrically connected to the driving circuit DC of the corresponding pixel area PA via one of the connecting electrodes 400. For example, the first electrode 510 of each pixel area PA can be in direct contact with one of the connecting electrodes 400 by penetrating the upper planarization layer 182, and each of the connecting electrodes 400 can be in direct contact with the second source electrode 227 of one of the pixel areas PA by penetrating the lower planarization layer 181. Thus, in the display apparatus according to the embodiment of the present disclosure, the light-emitting device 500 of each pixel area PA can be stably connected to the driving circuit DC of the corresponding pixel area PA.

A signal applied to the second electrode 530 of each pixel area PA can be a same as a signal applied to the second electrode 530 of adjacent pixel area PA. For example, a second power voltage can be applied to the second electrode 530 of each pixel area PA. The second power voltage can be different from the first power voltage applied through the first power voltage supply line PL. For example, the first power voltage can be a positive power voltage (VDD), and the second power voltage can be a negative power voltage (VSS).

The second electrode 530 of each pixel area PA can be electrically connected to the second electrode 530 of adjacent pixel area PA. For example, the second electrode 530 of each pixel area PA can be in direct contact with the second electrode 530 of adjacent pixel area PA. The second electrode 530 of each pixel area PA can extend onto the bank insulating layer 190. For example, the second electrode 530 of each pixel area PA can be formed simultaneously with the second electrode 530 of adjacent pixel area PA. Thus, in the display apparatus according to the embodiment of the present disclosure, a process of forming the second electrode 530 in each pixel area PA may be simplified.

An encapsulation structure 600 can be disposed on the second electrode 530 of each pixel area PA. The encapsulation structure 600 can prevent the damage of the light-emitting device 500 in each pixel area PA due to the external impact and moisture. For example, the light-emitting device 500 of each pixel area PA can be completely covered by the encapsulation structure 600. The encapsulation structure 600 can have a multi-layer structure. For example, the encapsulation structure 600 can include a first encapsulating layer 610, a second encapsulating layer 620 and a third encapsulating layer 630, which are sequentially stacked. The second encapsulating layer 620 can have a relative higher fluidity than the first encapsulating layer 610 and the third encapsulating layer 630. For example, the first encapsulating layer 610 and the third encapsulating layer 630 can be an inorganic encapsulating layer made of an inorganic insulating material, and the second encapsulating layer 620 can be an organic encapsulating layer made of an organic insulating material.

A touch sensor TS can be disposed on the encapsulation structure 600. The touch sensor TS can detect a touch of the user or a tool. For example, the touch sensor TS can include touch electrodes 710 and bridge electrodes 720 connecting between the touch electrodes 710.

The touch electrodes 710 and the bridge electrodes 720 can include a conductive material. The touch electrodes 710 and the bridge electrodes 720 can have a material having a relative small resistance. For example, the touch electrodes 710 and the bridge electrodes 720 can include a metal. Some of light passing through the encapsulation structure 600 can be blocked by the touch electrodes 710 or the bridge electrode 720. The touch electrode 710 and the bridge electrode 720 can be disposed outside the emission area EA defined in each pixel area PA. That is, in the display apparatus according to the embodiment of the present disclosure, the emission area EA of each pixel area PA can't overlap the touch electrodes 710 and the bridge electrodes 720. Thus, in the display apparatus according to the embodiment of the present disclosure, the loss of the light emitted from the emission area EA of each pixel area PA due to the touch sensor TS can be prevented.

At least some of the bridge electrodes 720 can be disposed on a different layer from the touch electrodes 710. For example, in the display apparatus according to the embodiment of the present disclosure, a touch buffer layer 701 can be disposed on the encapsulation structure 600, some of the bridge electrodes 720 disposed on the touch buffer layer 701 can be covered by a touch insulating layer 750, and the touch electrodes 710 can be disposed on the touch insulating layer 750. The touch buffer layer 701 and the touch insulating layer 750 can include an insulating material. For example, the touch buffer layer 701 and the touch insulating layer 750 can be an inorganic insulating layer made of an inorganic insulating material. Thus, in the display apparatus according to the embodiment of the present disclosure, the touch electrodes 710 can be connected in various directions by the bridge electrodes 720.

An optical insulating layer 800 can be disposed on the touch sensor TS. The optical insulating layer 800 can prevent the damage of the touch sensor TS due to the external impact and moisture. For example, the touch electrodes 710 of the touch sensor TS can be covered by the optical insulating layer 800. The optical insulating layer 800 can include an insulating material. The optical insulating layer 800 can include a transparent material. A thickness difference due to the touch sensor TS can be removed by the optical insulating layer 800. For example, the optical insulating layer 800 can include a region overlapping with the touch sensor TS and a region overlapping with the emission area EA of each pixel area PA. Thus, in the display apparatus according to the embodiment of the present disclosure, the optical distance of the light emitted from the emission area EA of each pixel area PA can be sufficiently secured.

As shown in FIG. 1, the display panel DP of the display apparatus according to the embodiment of the present disclosure can include a display area AA in which the pixel areas PA are disposed, and a bezel area BZ disposed outside the display area AA. For example, the display area AA can be surrounded by the bezel area BZ. A gate driver GD electrically connected to the gate line GL, a data driver electrically connected to the data line DL, and a power unit electrically connected to the first power voltage supply lines PL can be disposed outside the display area AA. At least one of the gate driver GD, the data driver and the power unit can be disposed on the bezel area BZ of the device substrate 100. For example, the display apparatus according to the embodiment of the present disclosure can be a GIP (Gate In Panel) type display apparatus in which the gate driver GD is disposed within the bezel area BZ.

A pad area PAD in which external signal is applied can be disposed in the bezel area BZ. For example, in the display apparatus according to the embodiment of the present disclosure, the data driver disposed outside the display panel DP can be electrically connected to the data line DL through the pad area PAD. The pad area PAD can be disposed on a side surface of the display area AA.

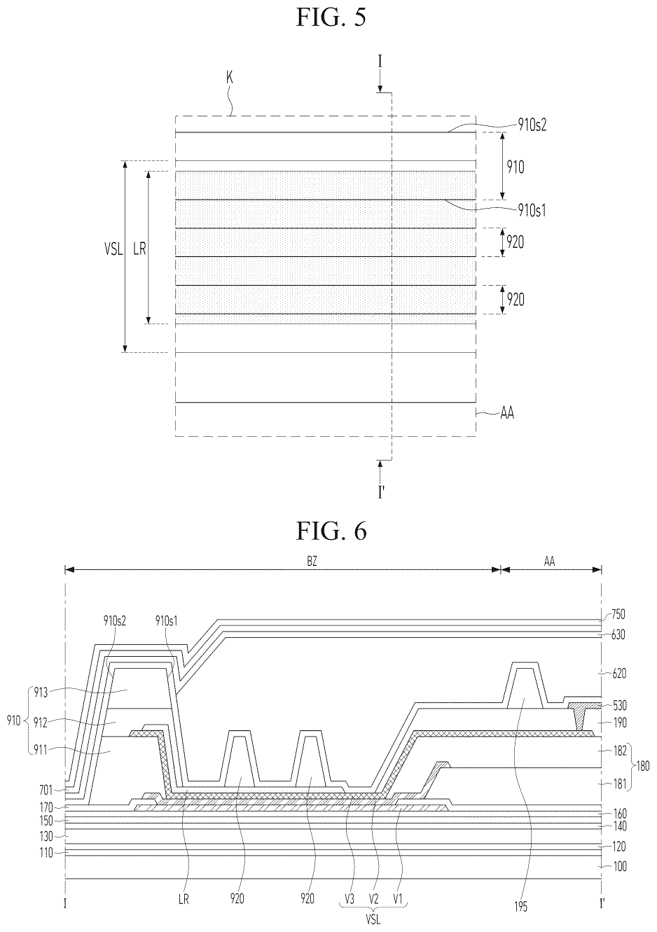

FIG. 5 is an enlarged view of K1 region in FIG. 1. FIG. 6 is a view taken along I-I′ of FIG. 5.

Referring to FIGS. 1 to 6, the display apparatus according to the embodiment of the present disclosure can include a second power voltage supply line VSL on the bezel area BZ. The second power voltage applied to the second electrode 530 of each pixel area PA can be supplied through the second power voltage supply line VSL. For example, the second electrode 530 of each pixel area PA can be electrically connected to the second power voltage supply line VSL. The second power voltage supply line VSL can be electrically connected to the power unit. For example, the second power voltage supply line VSL can be electrically connected to power pads VSP disposed in the bezel area BZ. The power pads VSP can be disposed side by side with the pad area PAD. For example, the pad area PAD can be disposed between the voltage pads VSP.

The second power voltage supply line VSL can extend along an edge of the display area AA. Thus, in the display apparatus according to the embodiment of the present disclosure, a process of connecting the second electrode 530 of each pixel area PA to the second power voltage supply line VSL can be simplified. The second power voltage supply line VSL can have a multi-layer structure. For example, the second power voltage supply line VSL can have a stacked structure of a first supply line V1, a second supply line V2 and a third supply line V3. The first supply line V1, the second supply line V2 and the third supply line V3 can include a conductive material. The second supply line V2 can be electrically connected to the first supply line V1, and the third supply line V3 can be electrically connected to the second supply line V2. For example, the second supply line V2 can include a region being in direct contact with the first supply line V1 and a region being in direct contact with the third supply line V3. Therefore, in the display apparatus according to the embodiment of the present disclosure, a resistance of the second power voltage supply line VSL can be minimized or at least reduced. That is, in the display apparatus according to the embodiment of the present disclosure, a voltage drop of the second power voltage applied through the second power voltage supply line VSL can be prevented.

The first supply line V1, the second supply line V2 and the third supply line V3 can be formed by using a process of forming a conductive layer disposed between the device substrate 100 and the second electrode 530 of each pixel area PA. For example, the first supply line V1 can be formed simultaneously with the second source electrode 227 of each pixel area PA, the second supply line V2 can be formed simultaneously with the connecting electrodes 400, and the third supply line V3 can be formed simultaneously with the first electrode 510 of each pixel area PA. The first supply line V1 can include an end portion disposed between the interlayer insulating layer 160 and the device passivation layer 170 of the bezel area BZ, an end portion of the second supply line V2 can be disposed between the lower planarization layer 181 and the upper planarization layer 182 of the bezel area BZ, and the third supply line V3 can include an end portion disposed between the upper planarization layer 182 and the bank insulating layer 190. The third supply line V3 can extend onto the display area AA. For example, the second electrode 530 of each pixel area PA can be in direct contact with the third supply line V3 by penetrating the bank insulating layer 190.

The encapsulation structure 600 on the second electrode 530 of each pixel area PA can extend beyond the display area AA. An encapsulation dam 910 for preventing the flow of the second encapsulating layer 620 which is an organic insulating layer can be disposed on the bezel area BZ. The second encapsulating layer 620 can be formed in a region defined by the encapsulation dam 910. For example, the display area AA can be surrounded by the encapsulation dam 910. The first encapsulating layer 610, the third encapsulating layer 630, the touch buffer layer 701 and the touch insulating layer 750 can extend beyond the encapsulation dam 910. For example, the third encapsulating layer 630 can be in direct contact with the first encapsulating layer 610 on an upper surface of the encapsulation dam 910 opposite to the device substrate 100. The encapsulation dam 910 can include a region disposed between the display area AA and the pad area PAD. Thus, in the display apparatus according to the embodiment of the present disclosure, the second encapsulating layer 620 can't flow into the pad area PAD. That is, in the display apparatus according to the embodiment of the present disclosure, the pad area PAD can't be covered by the second encapsulating layer 620. For example, in the display apparatus according to the embodiment of the present disclosure, the data driver disposed outside the display panel DP can be stably connected to the pad area PAD disposed on the bezel area BZ. Therefore, in the display apparatus according to the embodiment of the present disclosure, the distortion of a signal applied through the pad area PAD can be prevented.

A spacer 195 can be disposed on the bank insulating layer 190 of the display area AA. A portion of the second encapsulating layer 620 disposed in the display area AA can have a constant thickness by the spacer 195. Thus, in the display apparatus according to the embodiment of the present disclosure, the flow of the second encapsulating layer 620 toward the outside of the display area AA can be reduced by the spacer 195. For example, in the display apparatus according to the embodiment of the present disclosure, a portion of the second encapsulating layer 620 can include an end portion disposed around the spacer 195. Therefore, in the display apparatus according to the embodiment of the present disclosure, the flow of the second encapsulating layer 620 can be effectively blocked.

The encapsulation dam 910 can have a multi-layer structure. For example, the encapsulation dam 910 can include a first dam pattern 911, a second dam pattern 912 and a third dam pattern 913, which are sequentially stacked. The first dam pattern 911, the second dam pattern 912 and the third dam pattern 913 can include an insulating material. The first dam pattern 911, the second dam pattern 912 and the third dam pattern 913 can be formed by using a process of forming insulating layers 110, 120, 130, 140, 150, 160, 170, 180 and 190 disposed between the device substrate 100 and the encapsulation structure 600 of each pixel area PA. For example, the first dam pattern 911 can include a same material as the upper planarization layer 182, the second dam pattern 912 can include a same material as the bank insulating layer 190, and the third dam pattern 913 can include a same material as the spacer 195. The first dam pattern 911 can be formed by a process of forming connecting contact holes partially exposing the connecting electrode 400 of each pixel area PA in the upper planarization layer 182. The second dam pattern 912 can be formed by a process of forming openings defining the emission area EA of each pixel area PA in the bank insulating layer 190. The third dam pattern 913 can be formed by a process of patterning the spacer 195. Thus, in the display apparatus according to the embodiment of the present disclosure, the decrease in the process efficiency due to the formation of the encapsulation dam 910 can be prevented.

The lower buffer layer 110, the lower gate insulating layer 120, the separation insulating layer 130, the upper buffer layer 140, the upper gate insulating layer 150, the interlayer insulating layer 160 and the device passivation layer 170 can extend between the device substrate 100 and the first dam pattern 911 of the bezel area BZ. The first dam pattern 911 can be spaced apart from the lower planarization layer 181 and the upper planarization layer 182, and the bank insulating layer 190 covering an end portion of the upper planarization layer 182 toward the encapsulation dam 910 can be spaced apart from the second dam pattern 912. Thus, in the display apparatus according to the embodiment of the present disclosure, a space can be formed between the encapsulation dam 910 and the bank insulating layer 190. Therefore, in the display apparatus according to the embodiment of the present disclosure, the flow of the second encapsulating layer 620 can be effectively blocked.

The encapsulation dam 910 can include a first side surface 910s1 toward the display area AA and a second side surface 910s2 opposite to the first side surface 910s1. The second power voltage supply line VSL can include a region disposed between the display area AA and the encapsulation dam 910. For example, the first side surface 910s1 of the encapsulation dam 910 can overlap the second power voltage supply line VSL. An end portion of the first supply line V1, an end portion of the second supply line V2 and an end portion of the third supply line V3, which are opposite to the display area AA can overlap the encapsulation dam 910. For example, the third supply line V3 can include an end portion disposed between the first dam pattern 911 and the second dam pattern 912.

A dummy line LR can be disposed between the second power voltage supply line VSL and the first side surface 910s1 of the encapsulation dam 910. The dummy line LR can be disposed parallel to the second power voltage supply line VSL. For example, the dummy line LR can extend along between the third supply line V3 and the first side surface 910s1 of the encapsulation dam 910. The dummy line LR can overlap the second power voltage supply line VSL. For example, the dummy line LR can have a smaller size than the second power voltage supply line VSL. The first side surface 910s1 of the encapsulation dam 910 can include a region overlapping with the dummy line LR. The dummy line LR can extend between the first dam pattern 911 and the second dam pattern 912. For example, an end portion of the dummy line LR can be covered by the second dam pattern 912 on the first dam pattern 911.

A process of forming the connecting contact holes in the upper planarization layer 182, a process of forming the opening in the bank insulating layer 190 and a process of patterning the spacer 195 can include an exposure process using light. That is, in the display apparatus according to the embodiment of the present disclosure, the first dam pattern 911, the second dam pattern 912 and the third dam pattern 913 of the encapsulation dam 910 can be formed by an exposure process using light. The dummy line LR can have a smaller reflectivity than the second power voltage supply line VSL. For example, a reflectivity of the dummy line LR can be less than a reflectivity of the third supply line V3. Thus, in the display apparatus according to the embodiment of the present disclosure, the amount of light reflected by the dummy line LR can be smaller than the amount of light reflected by the second power voltage supply line VSL in an exposure process of forming the second dam pattern 912 and the third dam pattern 913.

Generally, in an exposure process of a second material layer disposed on a first material layer, light reflected by the first material layer can be irradiated to a lower end portion of the second material layer, and the lower end portion of the second material layer irradiated with the light reflected by the first material layer can be over-etched. For example, the amount of the light reflected by the first material layer is increased, a shape of a pattern formed by an exposure process of the second material layer can't be maintained, or a side surface of the pattern formed by an exposure process of the second material layer can have a large inclination angle. Thus, in the display apparatus according to the embodiment of the present disclosure, the amount of the light reflected in an exposure process of forming the second dam pattern 912 and the third dam pattern 913 can be reduced by the dummy line LR disposed between the second power voltage supply line VSL and the first side surface 910s1 of the encapsulation dam 910, and the first side surface 910s1 of the encapsulation dam 910 overlapping with the second power voltage supply line VSL can be stably formed. And, in the display apparatus according to the embodiment of the present disclosure, the first side surface 910s1 of the encapsulation dam 910 including a side surface of the second dam pattern 912 and a side surface of the third dam pattern 913 can be formed with a gentle slope. Therefore, in the display apparatus according to the embodiment of the present disclosure, the penetration of the external moisture through the encapsulation dam 910 can be reduced.

The dummy line LR can include a conductive material. For example, the dummy line LR can include a metal having a smaller reflectivity than the first supply line V1, the second supply line V2 and the third supply line V3 of the second power voltage supply line VSL. The second power voltage supply line VSL can be electrically connected to the dummy line LR. For example, a portion of the dummy line LR can be in direct contact with the third supply line V3. Thus, in the display apparatus according to the embodiment of the present disclosure, the resistance of the second power voltage supply line VSL can be minimized or at least reduced.

At least one middle stopper 920 can be disposed between the first side surface 910s1 of the encapsulation dam 910 and the display area AA. The middle stopper 920 can have a smaller size than the encapsulation dam 910. For example, the middle stopper 920 can be formed simultaneously with the second dam pattern 912 and/or the third dam pattern 913. The flow of the second encapsulating layer 620 on the bezel area BZ can be reduced by the middle stopper 920. Thus, in the display apparatus according to the embodiment of the present disclosure, the flow of the second encapsulating layer 620 can be effectively blocked. For example, in the display apparatus according to the embodiment of the present disclosure, a portion of the second encapsulating layer 620 can include an end portion disposed around the middle stopper 920.

The middle stopper 920 can overlap the second power voltage supply line VSL. The dummy line LR can extend between the second power voltage supply line VSL and the middle stopper 920. Thus, in the display apparatus according to the embodiment of the present disclosure, the middle stopper 920 can be stably formed by an exposure process. Therefore, in the display apparatus according to the embodiment of the present disclosure, the production energy can be reduced by the process optimization.

Accordingly, the display apparatus according to the embodiment of the present disclosure can comprise the light-emitting device 500 on the display area AA of the device substrate 100, the second power voltage supply line VSL on the bezel area BZ of the device substrate 100, the dummy line LR on the second power voltage supply line VSL of the bezel area BZ and the encapsulation dam 910 on the dummy line LR, wherein the first side surface 910s1 of the encapsulation dam 910 toward the display area AA can include a region overlapping with the second power voltage supply line VSL and the dummy line LR, wherein the dummy line can have a smaller reflectivity than the second power voltage supply line VSL. Thus, in the display apparatus according to the embodiment of the present disclosure, the reflection of the light irradiated in an exposure process of forming the encapsulation dam 910 can be reduced. Therefore, in the display apparatus according to the embodiment of the present disclosure, the encapsulation dam 910 can be stably formed by an exposure process.

The display apparatus according to the embodiment of the present disclosure is described that the driving circuit DC consists of the first thin film transistor TR1, the second thin film transistor TR2 and the storage capacitor Cst. However, in the display apparatus according to another embodiment of the present disclosure, the driving circuit DC can include a driving thin film transistor and at least one switching thin film transistor. For example, in the display apparatus according to another embodiment of the present disclosure, the driving circuit DC can further include a third thin film transistor to initialize the storage capacitor Cst according to the gate signal. The third thin film transistor can include a third semiconductor pattern, a third gate electrode, a third drain electrode and a third source electrode. The third gate electrode can be electrically connected to the gate line GL, the third drain electrode can be electrically connected to an initial line applying a signal for the initialization of the storage capacitor Cst. Thus, in the display apparatus according to another embodiment of the present disclosure, the degree of freedom in the configuration of the driving circuit DC can be improved.

In the display apparatus according to the embodiment of the present disclosure, the location and the electric connection of the first drain electrode 215, the first source electrode 217, the second drain electrodes 225 and the second source electrode 227 in each driving circuit DC can vary depending on the configuration of the corresponding driving circuit DC and/or the type of the corresponding thin film transistors TR1 and TR2. For example, in the display apparatus according to another embodiment of the present disclosure, the second gate electrode 223 can be electrically connected to the first drain electrode 215. Thus, in the display apparatus according to another embodiment of the present disclosure, the degree of freedom in the configuration of each driving circuit DC and the type of each thin film transistor TR1 and TR2 can be improved.

The display apparatus according to the embodiment of the present disclosure is described that the second semiconductor pattern 221 of each pixel area PA is disposed on a different layer from the first semiconductor pattern 211 of the corresponding pixel area PA. However, in the display apparatus according to another embodiment of the present disclosure, the second semiconductor pattern 221 of each pixel area PA can be disposed on a same layer as the first semiconductor pattern 211 of the corresponding pixel area PA. For example, in the display apparatus according to another embodiment of the present disclosure, the second semiconductor pattern 221 of each pixel area PA can include a same material as the first semiconductor pattern 211 of the corresponding pixel area PA. The second semiconductor pattern 221 of each pixel area PA can be formed simultaneously with the first semiconductor pattern 211 of the corresponding pixel area PA. Thus, in the display apparatus according to another embodiment of the present disclosure, the degree of freedom in the configuration of each pixel area PA can be improved.

The display apparatus according to the embodiment of the present disclosure is described that the dummy line LR includes a conductive material. However, in the display apparatus according to another embodiment of the present disclosure, the dummy line LR can be formed of an insulating material. For example, in the display apparatus according to another embodiment of the present disclosure, the dummy line LR can be an inorganic insulating layer made of an inorganic insulating material, such as silicon oxide (SiOx) and silicon nitride (SiNx). Thus, in the display apparatus according to another embodiment of the present disclosure, the reflection of the light in an exposure process of forming the second dam pattern 912 and the third dam pattern 913 can be greatly reduced by the dummy line LR. Therefore, in the display apparatus according to another embodiment of the present disclosure, the encapsulation dam 910 can be stably formed by an exposure process.

In the display apparatus according to another embodiment of the present disclosure, the dummy line LR can include a material capable of absorbing light. For example, in the display apparatus according to another embodiment of the present disclosure, the dummy line LR can include a black dye, such as carbon black. Thus, in the display apparatus according to another embodiment of the present disclosure, the reflection of the light irradiated in an exposure process of forming the first side surface 910s1 of the encapsulation dam 910 can be significantly reduced. Therefore, in the display apparatus according to another embodiment of the present disclosure, the stability of the encapsulation dam 910 formed by an exposure process can be significantly increased.

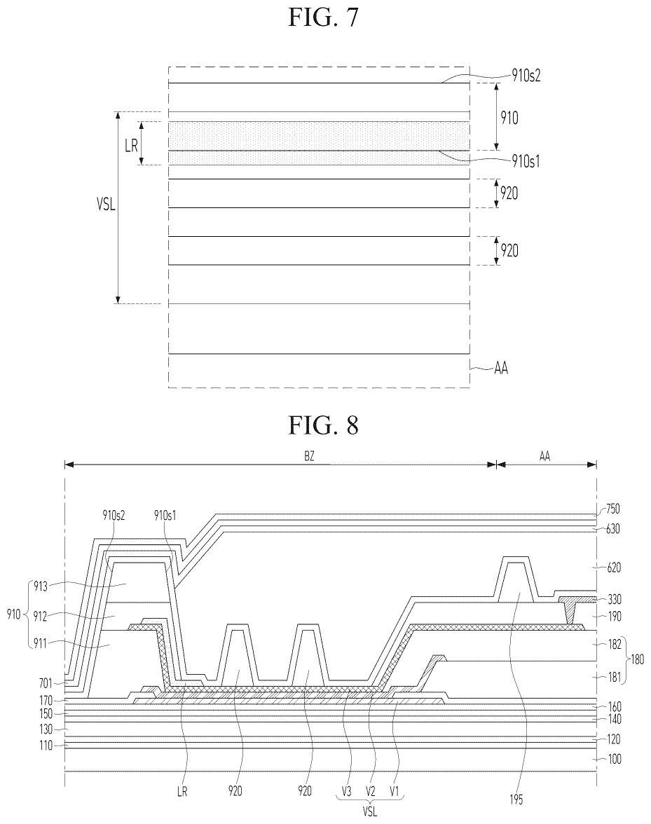

The display apparatus according to the embodiment of the present disclosure is described that the middle stopper 920 is formed by an exposure process. However, in the display apparatus according to another embodiment of the present disclosure, the middle stopper 920 can be formed by various ways. For example, in the display apparatus according to another embodiment of the present disclosure, the middle stopper 920 can be disposed outside the dummy line LR, as shown in FIGS. 7 and 8. An end portion of the dummy line LR toward the display area AA can be disposed between the encapsulation dam 910 and the middle stopper 920. Thus, in the display apparatus according to another embodiment of the present disclosure, the degree of freedom in a process of forming the middle stopper 920 can be improved.

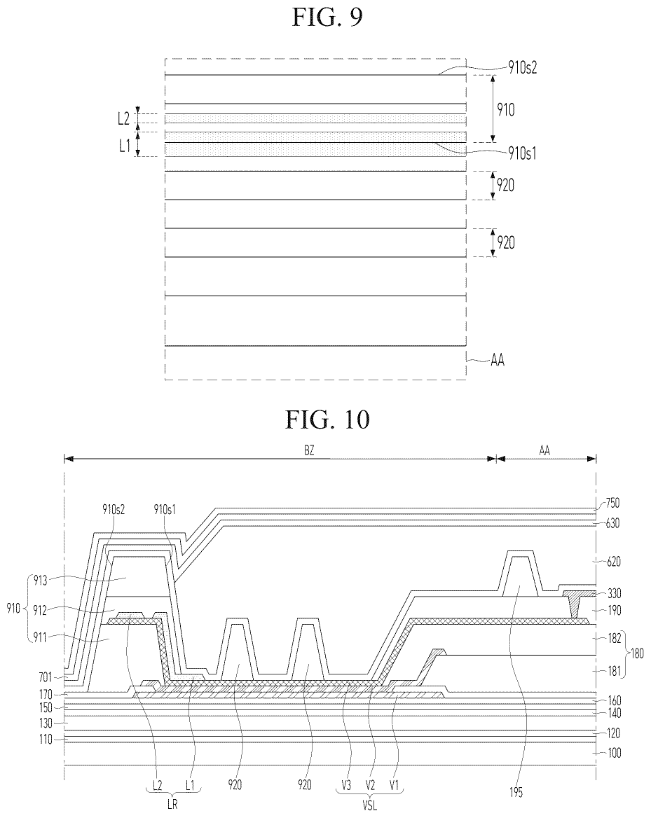

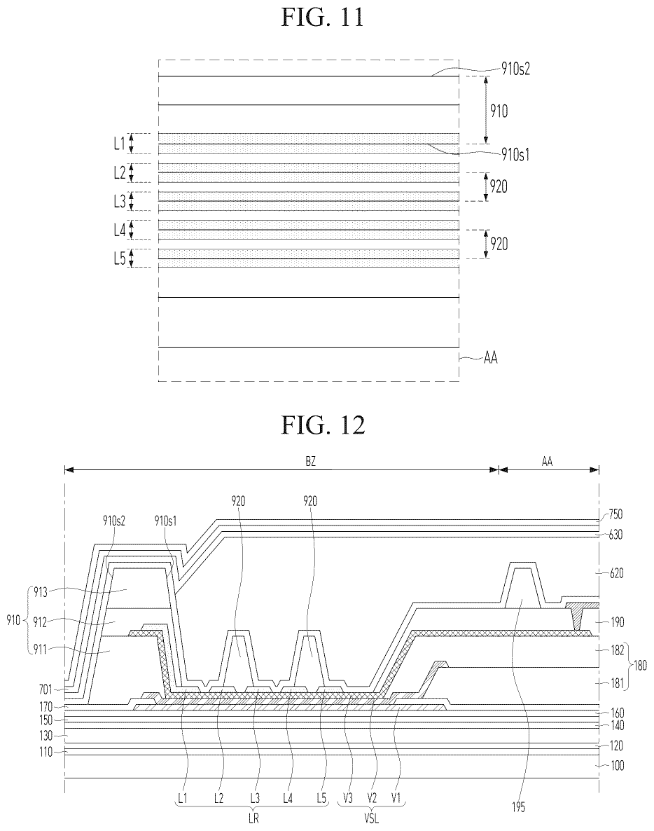

In the display apparatus according to another embodiment of the present disclosure, the dummy line LR can include a separated region. For example, in the display apparatus according to another embodiment of the present disclosure, the dummy line LR can include a first line L1 overlapping with the first side surface 910s1 of the encapsulation dam 910 and a second line Le covered by the second dam pattern 912 on the first dam pattern 911, as shown in FIGS. 9 and 10. Thus, in the display apparatus according to another embodiment of the present disclosure, the light reflected toward an upper surface of the second dam pattern 912 opposite toe the device substrate 100 can be reduced in an exposure process of forming the second dam pattern 912 overlapping with an end portion of the third supply line V3. Therefore, in the display apparatus according to another embodiment of the present disclosure, the stability of the second dam pattern 912 formed by an exposure process can be increased.

In the display apparatus according to another embodiment of the present disclosure, the first line L1 of the dummy line LR overlapping with the first side surface 910s1 of the encapsulation dam 910 can be spaced apart from a portion of the dummy line LR disposed outside the encapsulation dam 910. For example, in the display apparatus according to another embodiment of the present disclosure, the dummy line LR can include a second line L2 disposed outside the first line L1, a third line L3 disposed outside the second line L2, a fourth line L4 disposed outside the third line L3 and a fifth line L4 disposed outside the fourth line L4, and a side surface of each middle stopper 920 disposed between the encapsulation dam 910 and the display area AA can overlap one of the second line L2, the third line L3, the fourth line L4 and the fifth line L5. Thus, in the display apparatus according to another embodiment of the present disclosure, the degree of freedom in the shape of the dummy line LR can be improved.

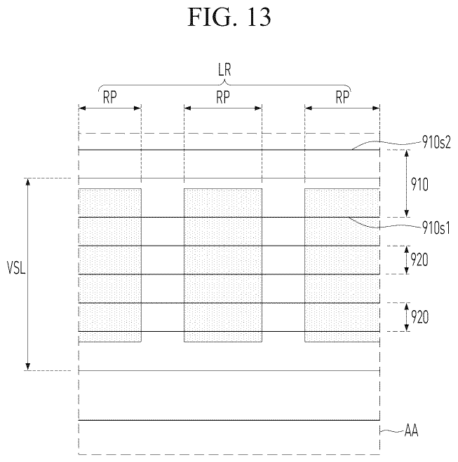

The display apparatus according to the embodiment of the present disclosure is described that the dummy line LR extends parallel to the second power voltage supply line VSL. However, in the display apparatus according to another embodiment of the present invention, the dummy line LR can have various shapes. For example, in the display apparatus according to another embodiment of the present disclosure, the dummy line LR can include dummy patterns RP disposed side by side along the second power voltage supply line VSL, as shown in FIG. 13. Thus, in the display apparatus according to another embodiment of the present disclosure, the amount of the light reflected in an exposure process of forming the second dam pattern and the third dam pattern can be adjusted by a size of each dummy pattern RP and an area of the second power voltage supply line VSL exposed between adjacent dummy patterns RP. That is, in the display apparatus according to another embodiment of the present disclosure, the inclination of the first side surface 910s1 can be adjusted by the amount of the light reflected by the dummy line LR and the second power voltage supply line VSL in an exposure process of forming the second dam pattern and the third dam pattern. For example, in the display apparatus according to another embodiment of the present disclosure, a spacer between adjacent dummy patterns RP can have a smaller size than each dummy pattern RP. Therefore, in the display apparatus according to another embodiment of the present disclosure, the stability of the encapsulation dam 910 formed by an exposure process can be effectively increased. And, in the display apparatus according to another embodiment of the present disclosure, the degree of freedom in the material of the dummy line LR can be improved

In the result, the display apparatus according to the embodiments of the present disclosure may comprise the light-emitting device disposed on the display area of the device substrate, the power voltage supply line disposed outside the display area, the dummy line disposed on the power voltage supply line and the encapsulation dam disposed on the dummy line, wherein the encapsulation dam can include the first side surface overlapping with the power voltage supply line and the dummy line, and wherein the amount of the light reflected by the dummy line can be smaller than the amount of the light reflected by the power voltage supply line. Thus, in the display apparatus according to the embodiments of the present disclosure, the reflection of the light irradiated in an exposure process of forming the encapsulation dam can be reduced. Thereby, in the display apparatus according to the embodiments of the present disclosure, the encapsulation dam can be stably formed. And, in the display apparatus according to the embodiments of the present disclosure, the production energy can be reduced by the process optimization.

What is claimed is:

1. A display apparatus, comprising:
a device substrate including a display area and a bezel area, the bezel area disposed outside the display area;
a power voltage supply line on the bezel area of the device substrate;
an encapsulation dam on the power voltage supply line, the encapsulation dam including a first side surface toward the display area; and
a dummy line between the power voltage supply line and the first side surface of the encapsulation dam,
wherein the first side surface of the encapsulation dam overlaps the power voltage supply line and the dummy line, and
wherein a reflectivity of the dummy line is less than a reflectivity of the power voltage supply line.

2. The display apparatus according to claim 1, wherein a size of the dummy line is smaller than a size of the power voltage supply line.

3. The display apparatus according to claim 1, wherein the dummy line includes a conductive material.

4. The display apparatus according to claim 3, wherein the dummy line includes a metal.

5. The display apparatus according to claim 3, wherein the power voltage supply line is electrically connected to the dummy line.

6. The display apparatus according to claim 5, wherein the power voltage supply line includes a first supply line and a second supply line disposed on the first supply line, and
wherein the second supply line including a different material from the first supply line includes a region in contact with the dummy line.

7. The display apparatus according to claim 1, wherein the dummy line includes a first line overlapping with the first side surface of the encapsulation dam and a second line spaced apart from the first line.

8. The display apparatus according to claim 7, further comprising a middle stopper between the display area and the encapsulation dam, a size of the middle stopper being smaller than a size of the encapsulation dam,
wherein a side surface of the middle stopper overlaps the power voltage supply line and the second line.

9. The display apparatus according to claim 1, wherein the encapsulation dam includes a first dam pattern and a second dam pattern disposed on the first dam pattern, and
wherein the dummy line extends between the first dam pattern and the second dam pattern.

10. The display apparatus according to claim 9, wherein the dummy line includes an end portion covered by the second dam pattern.

11. A display apparatus, comprising:
a display area surrounded by an encapsulation dam;
a power voltage supply line disposed outside the display area, the power voltage supply line extending an edge of the display area; and
a dummy line overlapping with the power voltage supply line, the dummy line extending parallel to the power voltage supply line,
wherein the encapsulation dam includes a first side surface toward the display area and a second side surface opposite to the first side surface,
wherein the first side surface of the encapsulation dam includes a region overlapping with the power voltage supply line, and
wherein loss of light due to the dummy line disposed between the power voltage supply line and the first side surface of the encapsulation dam is greater than loss of light due to the power voltage supply line.

12. The display apparatus according to claim 11, wherein the dummy line includes an insulating material.

13. The display apparatus according to claim 11, wherein the dummy line includes a plurality of dummy patterns disposed side by side along the power voltage supply line.

14. The display apparatus according to claim 13, wherein a size of a space between adjacent dummy patterns of the plurality of dummy patterns is smaller than a size of each dummy pattern of the plurality of dummy patterns.

15. The display apparatus according to claim 11, further comprising a light-emitting device in the display area,
wherein the light-emitting device includes a first electrode, a light-emitting unit and a second electrode, the first electrode, the light-emitting unit and the second electrode being sequentially stacked,
wherein one of layers constituting the power voltage supply line includes a same material as the first electrode of the light-emitting device, and
wherein the second electrode of the light-emitting device is electrically connected to the power voltage supply line.
